(19) United States
(12) Patent Application Publication
(10) Pub. No.: US 2012/0119264 A1
(43) Pub. Date: May 17, 2012

(54) BUILT-IN VERY HIGH SENSITIVITY IMAGE SENSOR

(75) Inventors: Yvon Cazaux, Grenoble (FR); Benoít Giffard, Grenoble (FR)

(73) Assignee: COMMISSARIAT A L'ENERGIE ATOMIQUE ET AUX ENERGIE ALTERNATIVES, Paris (FR)

(21) Appl. No.: 13/319,782

(22) PCT Filed: May 11, 2010
(86) PCT No.: PCT/FR10/50919

§ 371 Date: Jan. 23, 2012

(30) Foreign Application Priority Data
May 14, 2009 (FR) 0953192

(51) Int. Cl. H01L 31/112

(52) U.S. Cl. 257/222; 257/E31.078

(57) ABSTRACT

A basic device for an image sensor includes a photodiode consisting of a doped area having a first type of conductivity and formed at the surface of a semiconductor substrate having a second type of conductivity, adapted to be biased at a first reference voltage, wherein the photodiode is combined with a device for the transfer, multiplication and insulation of charges, the photodiode being a fully depleted one and including, at the surface of the doped area having a first type of conductivity, a strongly doped region having the second type of conductivity and adapted to be biased at a second reference voltage.

### FIELD OF THE INVENTION

The present invention relates to the field of integrated images sensors and, more specifically, to the field of sensors enabling a fine detection under a low lighting.

### DISCUSSION OF PRIOR ART

Many integrated image capture devices are known. The most current structure of such sensors comprises a plurality of elementary detection devices or pixels, each comprising a photodiode formed in a semiconductor substrate, associated with a charge transfer device and with a circuit for reading the charges which have been transferred. It is generally desired to minimize the number of sensor elements by using one read circuit for several photodiodes.

When an image sensor receives a light beam, the incident photons penetrate into the semiconductor substrate and form electron/hole pairs in this substrate. The electrons of these pairs are then captured by the photodiode, and transferred by the charge transfer transistor towards the associated read circuit.

US patent application 2007/0176213 describes a structure comprising, in addition to the above-mentioned elements, devices, associated with each pixel, capable of amplifying the electrons photogenerated in this pixel to improve the sensitivity of the sensors. To perform this amplification or charge multiplication, it is known to use the techniques associated with CCD (charge coupled device) registers, that is, to form, at the substrate surface, an assembly of alternately biased insulated metal gates. Such an alternated biasing of the insulated gates enables, by so-called electronic avalanche effect, to multiply the photogenerated electrons.

FIG. 1 illustrates a pixel of an image sensor comprising a charge multiplication stage and FIGS. 2A to 2E are voltage curves illustrating the operation of this pixel in different steps of the detection.

The pixel of FIG. 1 is formed inside and on top of a P-type substrate 10 biased to a reference voltage, for example, the ground. In substrate 10, at the surface thereof, is formed a photodiode formed of a heavily-doped N-type region 12 (N+). The photodiode is illuminated by a light beam 13. An insulated transfer gate 14 controlled by a transfer signal V_{T} is placed in the vicinity of the photodiode. Several insulated gates enabling to multiply the charges by avalanche effect are formed next to transfer gate 14. In the shown example, four gates 16, 18, 20, 22 are respectively controlled by control signals Φ1, Φ2, Φ3, and Φ4. The representation of FIG. 1 is extremely simplified; in particular, it should be noted that in a real device, the most part of the surface of each pixel is assigned to the photodiode.

FIGS. 2A to 2E illustrate the voltage in substrate 10, in the plane of FIG. 1, in different steps of the image capture. In these drawings, a single electron storage, transfer, and multiplication cycle is described. The voltage illustrated in each of the drawings is the voltage in substrate 10, following a line which will be called “maximum potential line” hereinafter. This line runs, in depth in the substrate, through the points of highest biasing in front of the insulated gates and in the photodiode. It should be noted that, according to the voltage applied on the different insulated gates, the maximum biasing line runs through points of variable depth in the substrate. It should be noted that, in the following description, gate 16 will be called “first multiplication gate” although this gate also plays a role in the initial transfer step.

FIG. 2A shows the curve of the voltage in photodiode 12 and in substrate 10, in an initial phase of charge storage in photodiode 12. The illumination of the sensor of FIG. 1 causes the storage of electrons in region 12 and the voltage of this region, initially equal to V₁, decreases to reach a value V₂ which is a function of the number of stored electrons and thus of the number of incident photons. During the storage phase, voltage V_{T} applied to the transfer gate is zero to form a potential wall and avoid for electrons to come out from photodiode 12. Voltage Φ1, associated with first charge multiplication gate 16 is, preferably just before the transfer step V₃, greater than V₁, in anticipation of the next step.

At the step of FIG. 2B, a transfer voltage V_{T}, substantially equal to or slightly greater than V₁, is applied to transfer gate 14, while voltage Φ1 applied to first charge multiplication gate 16 is equal to V₃ (greater than V₁) and voltage Φ2 applied to second multiplication gate 18 is zero. The charges stored in photodiode 12 are thus transferred into the potential well formed, in substrate 10, under first multiplication gate 16.

At the step of FIG. 2C, voltage V_{T} (transfer gate) returns to a reference voltage while voltage Φ2 remains at this reference voltage, for example, equal to zero, which blocks the electrons in substrate region 10 located under gate 16. A new charge storage phase can then start at the level of photodiode 12.

At the step illustrated in FIG. 2D, voltage Φ1 applied to gate 16 is decreased to a low voltage V₄. The voltage of substrate 10 located under gate 16 is thus lowered. During this step, voltages V_{T} and Φ2 respectively applied to gates 14 and 18 are zero (reference voltage). Preferably, just before the next step, voltage Φ3 applied to gate 20 is set to a voltage V₅ much greater than voltage V₄, in anticipation of the next step.

At the step illustrated in FIG. 2E, voltage 12 applied to gate 18 increases fast to be on the order of voltage V₄, or slightly greater than V₄. Voltage Φ3 being equal to V₅ (much greater than V₄), the charges are transferred to the substrate region located under gate 20. The voltage difference between the region located under gate 18 (□ V₄) and under gate 20 (V₅) is sufficiently high to enable to multiply the charges by electronic avalanche effect. During this step, gate 22 is biased to a zero voltage to form a potential wall and to block the charges at the level of gate 20. As an example, voltage V₄ may be on the order of 1 V and voltage V₅ may be on the order of 10 V. It should be noted that the charge transfer step (FIG. 2B) may also take part in the charge amplification, the voltage applied to gate 16 during this step being then capable of causing a multiplication (high voltage).

For the charge multiplication by avalanche effect to be significant, the steps of FIGS. 2D and 2E are repeated several times. For this purpose, back and forth transfers are performed at the level of gates 14, 16, 18, 20, and 22, which enables to limit the number of gates to be formed.

A problem arises if the device remains under a very low lighting level for a long time, for example in the case where the image sensor is intended to detect images in a dark environment (for example, nocturnal images). In this case, it will be shown that the charge transfer during the step of FIG. 2B may be incomplete or be distorted. The signal originating from the sensor then has very degraded performances, especially in terms of signal-to-noise ratio.

Thus, a device enabling to detect and to transmit a high-quality signal, even under a low lighting, is needed.

### SUMMARY

An object of an embodiment of the present invention is to provide an image sensor providing a good detection under a low lighting.

Thus, an embodiment of the present invention provides an elementary device of an image sensor, comprising a photodiode formed of a doped area of a first conductivity type formed at the surface of a semiconductor substrate of a second conductivity type capable of being biased to a first reference voltage, the photodiode being associated with a charge transfer, multiplication, and insulation device, the photodiode being of fully depleted type and comprising, at the surface of the doped area of the first conductivity type, a heavily-doped region of the second conductivity type capable of being biased to a second reference voltage.

According to an embodiment of the present invention, the charge transfer, multiplication, and insulation device comprises a transfer gate, an insulating gate, and a plurality of multiplication gates capable of being biased to set the voltage of the underlying substrate and to enable the charge transfer, insulation, and multiplication by electronic avalanche effect.

According to an embodiment of the present invention, the charge transfer, multiplication, and insulation device comprises at least five gates.

According to an embodiment of the present invention, the first and second reference voltages are equal and are ground voltages.

According to an embodiment of the present invention, a doped layer of the first conductivity type is formed, at the surface of the substrate, in front of the charge transfer, multiplication, and insulation gates.

According to an embodiment of the present invention, the device further comprises an optical mask formed on the charge transfer, multiplication, and insulation device.

According to an embodiment of the present invention, the substrate is thinned and is intended to be illuminated from the surface opposite to that on which the charge transfer, multiplication, and insulation device is formed.

According to an embodiment of the present invention, the first conductivity type is type N.

The present invention also aims at an image sensor comprising a plurality of elementary devices such as hereabove.

### BRIEF DESCRIPTION OF THE DRAWINGS

The foregoing and other objects, features, and advantages of the present invention will be discussed in detail in the following non-limiting description of specific embodiments in connection with the accompanying drawings, among which:

FIG. 1, previously described, illustrates a conventional charge amplification image sensor;

FIGS. 2A to 2E are voltage curves illustrating the operation of the device of FIG. 1 when it is submitted to a significant lighting;

FIG. 3 shows the structure of FIG. 1 and FIGS. 4A to 4C are voltage curves illustrating an issue that may arise in this structure in the absence of any lighting or under a low lighting;

FIG. 5 illustrates an image sensor according to an embodiment of the present invention;

FIGS. 6 and 7 are voltage curves in the sensor of FIG. 5; and

FIG. 8 illustrates a variation of a device according to an embodiment of the present invention.

For clarity, the same elements have been designated with the same reference numerals in the different drawings and, further, as usual in the representation of integrated circuits, the various drawings are not to scale.

### DETAILED DESCRIPTION

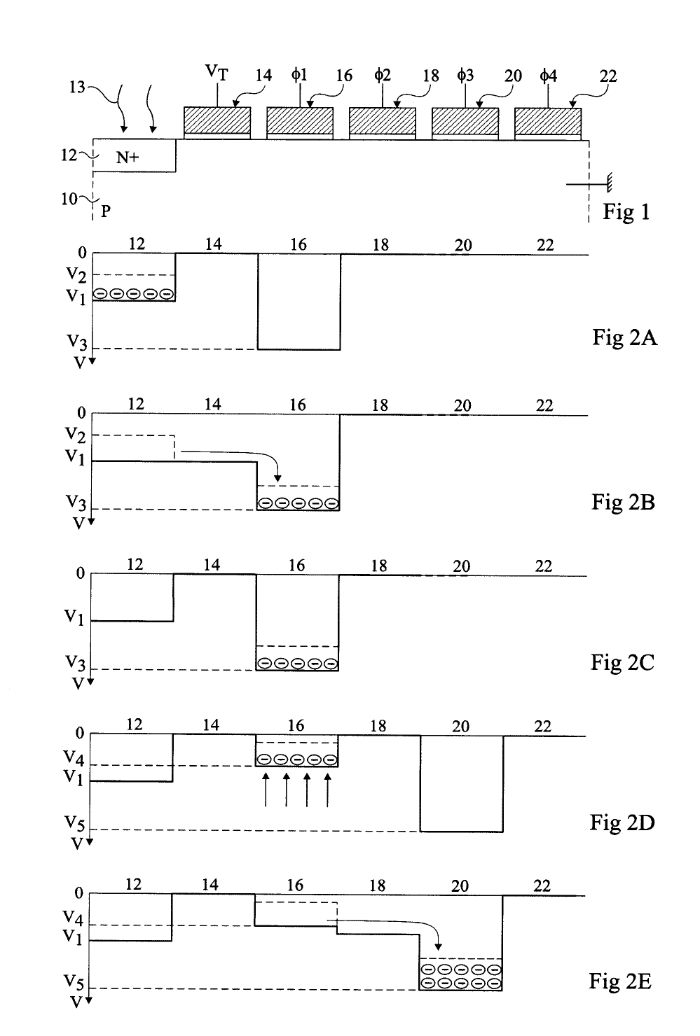

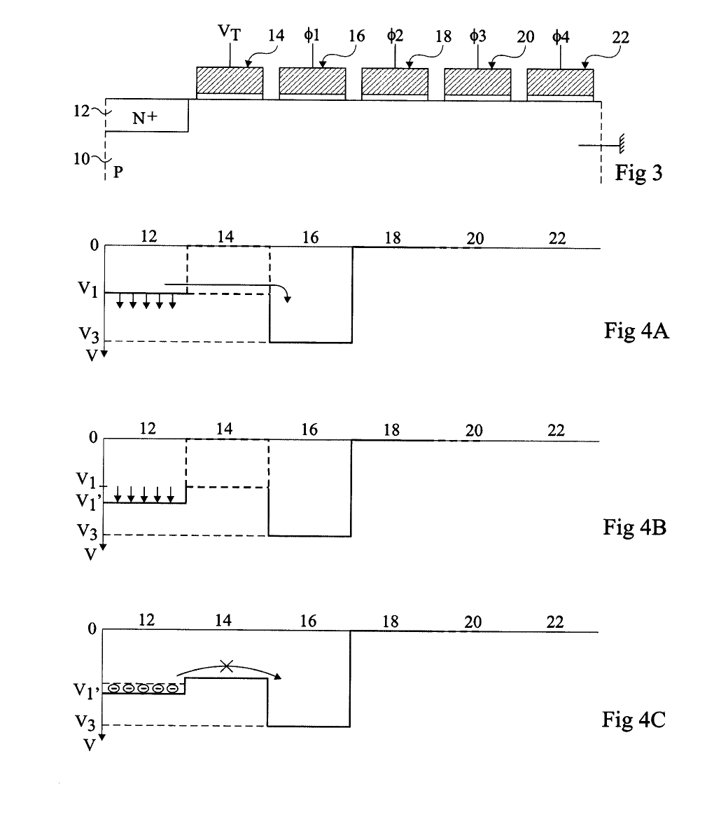

FIG. 3 shows the structure of FIG. 1, in the case of a quasi absent lighting (no light beam 13). The device comprises a photodiode 12 formed of a heavily-doped N-type region (N+) formed at the surface of a P-type substrate 10, an insulated transfer gate 14 formed at the surface of substrate 10 and controlled by a transfer signal V_{T}, and insulated charge multiplication gates 16, 18, 20, 22 respectively controlled by signals Φ1, Φ2, Φ3, Φ4.

FIGS. 4A to 4C are voltage curves in substrate 10, following the maximum potential lines, during different operating steps of the device of FIG. 3.

FIG. 4A illustrates the voltage in substrate 10 during a succession of charge storage and transfer steps (with voltage V_{T} of gate 14 varying between zero and V₁). When the photodiode is not illuminated, no electron/hole pair is created and the photodiode voltage should theoretically remain constant. However, it can be observed that said voltage increases progressively along storage/transfer cycles, to reach, in the shown example, a voltage V₁′ (FIG. 4B).

The voltage increase in the photodiode, in a succession of cycles under no or a very low lighting, is due to a leakage current between heavily-doped N-type photodiode 12 and the space charge area located in front of gate 16. During transfer phases (V_{T}=V₁), the voltages of the photodiode and of the channel formed under gate 14 are very close and the charges of region 12 leak through the channel located under gate 14 towards the potential well formed under gate 16, according to a low-inversion current law expressed in exp(−qV/kT), q being the elementary charge, V being the potential difference between gate 14 and photodiode 12, k being Boltzmann's constant, and T being the temperature. Thus the voltage of region 12 becomes greater than the facing voltage of gate 14. It should be noted that, in case of a significant lighting, this issue does not arise since the leakage current is then negligible as compared with the current resulting from the lighting. However, at a low lighting level, this phenomenon disturbs the charge injection into the multiplication stage, thus making this stage useless in the most critical cases where it should play an essential role.

Once voltage V₁′ has been reached, if there is a low lighting and a small amount of electrons is stored in photodiode 12 (FIG. 4C), the charge reading efficiency will be very poor, a small amount of electrons succeeding in passing the potential barrier formed by the region located under gate 14 in a transfer. Indeed, since the voltage in the photodiode has varied from V₁ to V₁′, one has V₁′>V_{T} during the transfer, which forms a potential wall preventing any transfer of the electrons stored in the photodiode or only enabling a partial transfer thereof. Further, if a sufficient amount of electrons for the transfer is stored in photodiode 12, the transfer is distorted due to the voltage variation during the period when photodiode is not illuminated (less charges than there where really stored in photodiode 12 are transferred).

Thus, in the case of a very low or of no lighting, the charge reading performed by the device of FIG. 3 is not good.

To solve this problem, the inventors provide using a specific photodiode and, more specifically, a photodiode in which the voltage of the electron capture region cannot increase above a predetermined threshold. The photogenerated charges can thus be properly read, including in cases of low lighting.

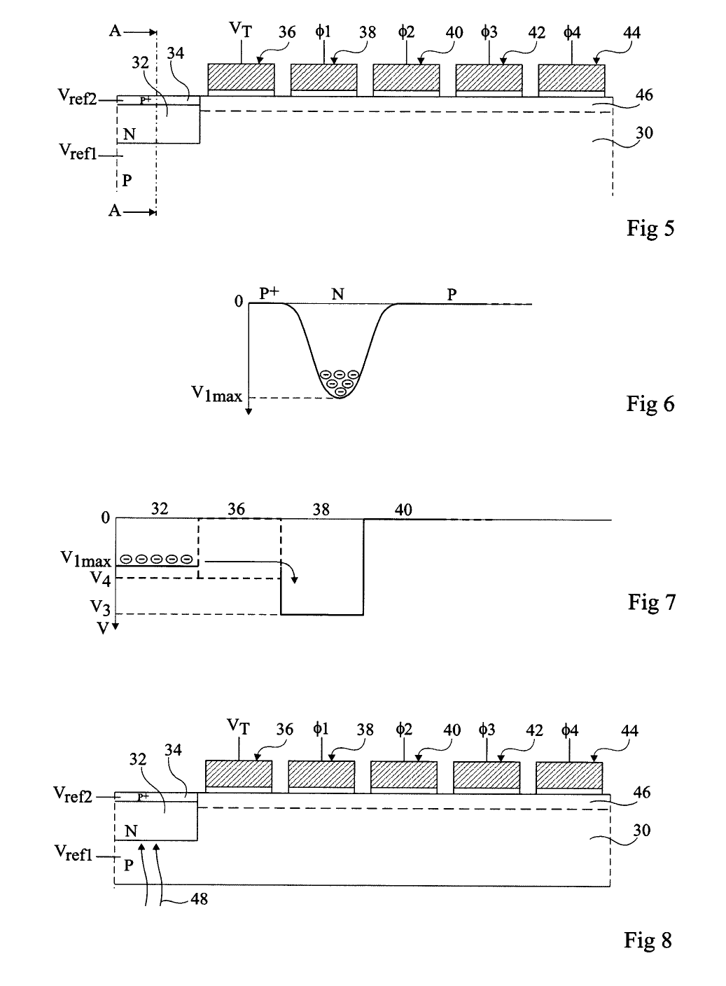

FIG. 5 illustrates such a photodiode. The inventors provide using a clamped-type fully depleted or pinned photodiode. The photodiode is formed in a P-type substrate 30 and comprises an N-type doped capture region 32 having a thin heavily-doped P-type region 34 (P+) extending at its surface. Substrate 30 is biased to a first reference voltage V_{ref1} and heavily-doped P-type region 34 is biased to a second reference voltage, V_{ref2}. The first and second reference voltages, V_{ref1} and V_{ref2}, may be equal and correspond to a ground voltage, but it should be noted that it may also be provided to bias substrate 30 and region 34 to different reference voltages.

The photodiode is associated with a transfer gate 36, with charge multiplication gates 38, 40, 42, and with an insulation gate 44 formed at the surface of substrate 30, close to the photodiode. Gates 36, 38, 40, 42, 44 have insulated gate structures and are respectively controlled with control signals V_{T}, Φ1, Φ2, Φ3, Φ4. Preferably, a protection layer (not shown), or optical mask, is provided above transfer gate 36, amplification or multiplication gates 38, 40, 42, and insulation gate 44, so that incident light beams generate no charges in the substrate located under these gates.

The dopings of areas 32 and 34 are adjusted so that heavily-doped P-type area 34 fully depletes N-type area 32. Thus, when a thermodynamic equilibrium has not been reached and in the absence of any lighting, the voltage of area 32 is only set by the dopings of the photodiode and of the substrate, which avoids the low inversion state during the charge transfer towards the substrate located in front of gate 38. It should be noted that, conversely to what is shown in FIG. 5, in a real device, the most part of the surface area of each pixel is assigned to the photodiode (detection area of the device).

FIG. 6 is a voltage curve of the structure illustrated in FIG. 5 in a cross-section A-A, along the height of the device at the level of photodiode 32/34, in the case where V_{ref1}=V_{ref2}=0 V. When the photodiode is not illuminated, the voltage within N-type region 34 is fully determined by the dopings of regions 30, 32, 34 and, thus, region 32 at most reaches a voltage V₁ₘₐₓ.

The disadvantages discussed in relation with FIGS. 3 and 4A to 4C, that is, the variation of the maximum voltage in the photodiode capture region in case of a low lighting, are thus avoided. When the photodiode is illuminated, the voltage of region 32 decreases and when the charge transfer occurs, the voltage of region 32 returns to V₁ₘₐₓ.

FIG. 7 illustrates a voltage curve identical to that shown in FIG. 4A (along the maximum potential line) in the case of the device of FIG. 5. In this case, even with no illumination of the photodiode, the voltage of 32 always remains equal to or smaller than V₁ₘₐₓ. Thus, all the charges photogenerated and stored in the photodiode are transferred in a transfer phase where voltage V_{T} passes to a voltage V₄, equal to or slightly greater than V₁ₘₐₓ, which makes the sensor efficient even in case of a very low lighting or after a long period with no lighting.

Once the electron transfer from the photodiode to the space charge located under gate 38 has been performed, a charge amplification cycle is conventionally carried out, by application of a significant electric field between two adjacent gates. Advantage is then taken from the electronic avalanche effect by forcing the charges to travel back and forth under gates 38, 40, and 42 to obtain a significant amplification. The amplification gain is adjusted by controlling the number of back and forth travels under gates 38, 40, and 42. Transfer gate 36 and insulation gate 44 are then used as potential walls to avoid for charges to come out of the device during the charge amplification. Gates 38 and 42 are alternately biased to create significant voltage differences allowing the electronic avalanche effect. It should be noted that the charge transfer, amplification, and insulation device may also be formed by combining more than five neighboring gates.

Optionally, a thin N-type doped layer 46 may be formed at the surface of substrate 30, in front of transfer gate 36, multiplication gates 38, 40, 42, and insulation gate 44. Thin layer 46 enables to slightly move away the maximum voltage point from the substrate surface to avoid parasitic phenomena (noise) often present at the interfaces between the gate insulator and the semiconductor substrate.

FIG. 8 illustrates a variation of the device of FIG. 5 wherein the image sensor is illuminated from the back side of substrate 30. The device of FIG. 8 differs from that of FIG. 5 in that substrate 30 is thinned and is illuminated from the surface opposite to that on which are formed transfer gate 36, charge multiplication gates 38, 40, 42, and insulation gate 44. During the build-up phase, a light beam 48 reaching the substrate generates electron/hole pairs therein and the electrons of these pairs are collected in the potential well formed by photodiode 32. Advantageously and conventionally, a beam arriving from the back side of a substrate comes across less obstacles and is more easily detectable than a beam arriving on the front surface of the substrate. The operation of this device is then similar to that described hereabove.

Specific embodiments of the present invention have been described. Various alterations, modifications, and improvements will occur to those skilled in the art. In particular, although a device where the useful photogenerated charges are electrons has been described herein, it should be noted that similar devices where the useful charges are holes may also be provided. To achieve this, the conductivity types of the different doped regions will be inverted, and the voltages applied to the different gates for the charge transfers will be of a sign opposite to those discussed hereabove.

The devices of FIGS. 5 and 8 may also be used in the case of strong lighting levels. In this case, it may be provided to adapt the integration or charge build-up time in the photodiode according to the lighting, by means of an adapted electronic circuit, to avoid the pixel saturation.

1. An elementary device of an image sensor, comprising a photodiode formed of a doped area of a first conductivity type formed at the surface of a semiconductor substrate of a second conductivity type capable of being biased to a first reference voltage, the photodiode being associated with a charge transfer, multiplication, and insulation device, the photodiode being of fully depleted type and comprising, at the surface of the doped area of the first conductivity type, a heavily-doped region of the second conductivity type capable of being biased to a second reference voltage.

2. The device of claim 1, wherein the charge transfer, multiplication, and insulation device comprises a transfer gate, an insulating gate, and a plurality of multiplication gates capable of being biased to set the voltage of the underlying substrate and to enable the transfer, insulation, and multiplication of the charges by electronic avalanche effect.

3. The device of claim 2, wherein the charge transfer, multiplication, and insulation device comprises at least five gates.

4. The device of claim 1, wherein the first and second reference voltages are equal and are ground voltages.

5. The device of claim 2, wherein a doped layer of the first conductivity type is formed, at the surface of the substrate, in front of the charge transfer, insulation, and multiplication gates.

6. The device of claim 1, further comprising an optical mask formed on the charge transfer, multiplication, and insulation device.

7. The device of claim 1, wherein the substrate is thinned and is intended to be illuminated from the surface opposite to that on which the charge transfer, multiplication, and insulation device is formed.

8. The device of any of claim 1, wherein the first conductivity type is type N.

9. An image sensor comprising a plurality of elementary devices according to claim 1.
